(19) United States
(12) Patent Application Publication
(10) Pub. No.: US 2021/0210606 A1
(43) Pub. Date: Jul. 8, 2021

(54) OXYGEN GETTERS FOR ACTIVATION OF GROUP V DOPANTS IN II-VI SEMICONDUCTOR MATERIALS

(71) Applicant: Alliance for Sustainable Energy, LLC, Golden, CO (US)

(72) Inventors: Eric Michael COLEGROVE, Denver, CO (US); Matthew Owen REESE, Golden, CO (US); Wyatt Keith METZGER, Louisville, CO (US); Craig Lyle PERKINS, Golden, CO (US)

(21) Appl. No.: 17/099,279

(22) Filed: Nov. 16, 2020

Related U.S. Application Data
(60) Provisional application No. 62/935,753, filed on Nov. 15, 2019.

(51) Int. Cl. H01L 29/227; H01L 29/22

(52) U.S. Cl. CPC H01L 29/227; H01L 31/02963; H01L 29/2203

(57) ABSTRACT

Disclosed herein are the use of materials that have high affinity for oxygen, “oxygen getters” (e.g. Al), in conjunction with group V dopants (e.g. As) in II-VI materials (e.g. CdTe, Cd(Se)Te), that enable p-type doping by reducing group V oxides found in as-grown II-VI materials, thereby freeing up the anionic form of the Group V element.

### CROSS-REFERENCE TO RELATED APPLICATIONS

This application claims priority under 35 U.S.C. § 119 to U.S. Provisional Patent Application No. 62/935,753 filed on 15 Nov. 2019, the contents of which are hereby incorporated in their entirety.

### CONTRACTUAL ORIGIN

The United States Government has rights in this invention under Contract No. DE-AC36-08G028308 between the United States Department of Energy and Alliance for Sustainable Energy, LLC, the Manager and Operator of the National Renewable Energy Laboratory.

### BACKGROUND

Group V doping in II-VI semiconductors materials is both challenging and potentially very valuable. The ability to more highly dope a semiconductor (achieve higher carrier concentrations) enables larger built-in charge and as a result larger built-in electric fields. Stronger electric fields in photovoltaics (PV) means higher open circuit voltages (Voc) and as a result higher solar power conversion efficiency. II-VI PV, such as CdTe-based PV, still suffers from a large Voc deficit when compared to the band-gap, so Voc has a lot of room for improvement. Doping needs to be balanced with other factors such as interface recombination, bulk lifetime, and stability in order to become viable in PV devices.

Previously, Cu and Cl chemistries have been used to achieve p-type doping in CdTe, but more recently it has been shown that doping with P, As, or Sb is possible, can enable higher carrier concentrations (more built-in charge), will not compromise lifetime, and may be significantly more stable than Cu. However, oxygen in group V doped samples may bond with group V elements limiting doping. Additionally, oxygen at the p-n junction interface is believed to be very important for low interface recombination.

So, there is a need to pull oxygen away from group V elements to effectively dope the material, while still maintaining oxygen at the p-n junction interface.

### SUMMARY

In an aspect, disclosed is a method for making a II-VI semiconductor material comprising a group V dopant wherein said method comprises the use of a getter selected from the group consisting of B, Al, Ga, Mg, Ti, Zr, Hf, Sc, Y, La, Cr, and Fe. In an embodiment, the getter is Al₂O₃. In an embodiment, the getter is AlCl₃.

Other objects, advantages, and novel features of the present invention will become apparent from the following detailed description of the invention when considered in conjunction with the accompanying drawings.

### BRIEF DESCRIPTION OF THE DRAWINGS

None.

### DETAILED DESCRIPTION

A challenge remaining in improving the performance of CdTe PV devices is in raising the open-circuit voltage of these devices, which is still relatively small compared to the CdTe material bandgap. One way to improve the Voc is to improve the ability to more-highly dope the absorber material, thus increasing the carrier concentration and raising the built-in electronic field. Recently, new methods to dope CdTe materials with Group V dopants (P, As, Sb, Bi) have been investigated as a promising alternative to improve the doping profile of CdTe films.

One problem with using Group V dopants, however, is their high affinity for forming Group V-oxide compounds, rather than exist in their ionic state on the Te-site in the CdTe crystal lattice. Disclosed herein are methods that provide an oxygen ‘getter’ material (such as aluminum) that outcompetes available oxygen to from getter-oxides rather than Group V oxides. These getter-oxides are benign in the crystal lattice and result in more available Group V atoms to freely dope the material.

Aluminum and other materials that can form oxides having large negative enthalpies of formation can be used to getter oxygen away from the group V elements while still maintaining the p-n junction interfacial oxides.

Previous work has used materials that exhibit a significant voltage deficit with interface recombination being likely for holding this technology back. Oxygen getters may enable group V doping without compromising the interface. In an embodiment, and as disclosed herein, are methods for the use of materials that have high affinity for oxygen, “oxygen getters” (e.g. Al), in conjunction with group V dopants (e.g. As) in II-VI materials (e.g. CdTe, Cd(Se)Te) that enables p-type doping by reducing group V oxides found in as-grown II-VI materials, thereby freeing up the anionic form of the Group V element.

Potential oxygen getters include B, Al, Ga, Mg, Ti, Zr, Hf, Sc, Y, La, Cr, Fe and their compounds, particularly halide compounds

Some considerations for choosing candidate oxygen getters include the enthalpy of formation of the getter oxide (e.g. Al₂O₃) relative to the group V oxide (e.g. As₂O₃), as well as the getter chloride (e.g. AlCl₃) and potentially any relevant oxychlorides. Without being limited by theory, a reason why the chloride (oxychloride) compounds may be of import is that chlorine will likely be present in the devices due to CdCl₂ or similar treatments. Optimally, the getter and any reactants it forms will be electronically inert (not introduce traps).

Examples with Aluminum and Arsenic are as follows:

ΔHf(kJ/mol): Al₂O₃=−1675.7; AlCl₃=−705.6; As₂O₃=−657.3

Application of Hess's Law to the above formation energies indicates that the reaction between arsenic oxide and aluminum metal to form alumina and free arsenic is strongly favored:

As₂O₃+2Al−>Al₂O₃+2As, ΔH_{reaction}=−1018 kJ/mol

Because Al₂O₃ has a more negative enthalpy of formation, it should be energetically favorable to have Aluminum introduced either in its elemental form or as a chloride to strip oxygen from any oxidized arsenic. Similarly, because aluminum oxide is more negative than its chloride, the oxide is also energetically favored. The wide bandgap of Al₂O₃ makes it insulating (electrically inert). It has been used for passivating in double heterostructures, so is known to be benign with CdTe and its alloys.

The foregoing disclosure has been set forth merely to illustrate the invention and is not intended to be limiting.

We claim:

1. A method for making a II-VI semiconductor material comprising a group V dopant wherein the method comprises the use of an oxygen getter composition of matter.

2. The method of claim 1, wherein the II-VI semiconductor material comprises CdTe.

3. The method of claim 1, wherein the II-VI semiconductor material comprises Cd(Se)Te.

4. The method of claim 1, wherein the getter is Al₂O₃.

5. The method of claim 1, wherein the getter is AlCl₃.

6. The method of claim 1, wherein the getter comprises Aluminum.

7. The method of claim 1, wherein the getter comprises Boron.

8. The method of claim 1, wherein the getter comprises Gallium.

9. The method of claim 1, wherein the getter comprises elements selected from the group consisting of Magnesium, Titanium, and Zirconium.

10. The method of claim 1, wherein the getter comprises elements selected from the group consisting of Hafnium, Scandium, Yttrium, Lanthanum, Chromium, and Iron.

11. A II-VI semiconductor material comprising a group V dopant and further comprising an oxygen getter composition of matter.

12. The II-VI semiconductor material of claim 11, wherein the II-VI semiconductor material comprises CdTe.

13. The II-VI semiconductor material of claim 11, wherein the II-VI semiconductor material comprises Cd(Se)Te.

14. The II-VI semiconductor material of claim 11, wherein the getter is Al₂O₃.

15. The II-VI semiconductor material of claim 11, wherein the getter is AlCl₃.

16. The II-VI semiconductor material of claim 11, wherein the getter comprises Aluminum.

17. The II-VI semiconductor material of claim 11, wherein the getter comprises Boron.

18. The II-VI semiconductor material of claim 11, wherein the getter comprises Gallium.

19. The II-VI semiconductor material of claim 11, wherein the getter comprises elements selected from the group consisting of Magnesium, Titanium, and Zirconium.

20. The II-VI semiconductor material of claim 11, wherein the getter comprises elements selected from the group consisting of Hafnium, Scandium, Yttrium, Lanthanum, Chromium, and Iron.
